(19) United States
(12) Patent Application Publication
(10) Pub. No.: US 2023/0175892 A1
(43) Pub. Date: Jun. 8, 2023

(54) METHOD FOR CONTROLLING AN EVAPORATION RATE OF SOURCE MATERIAL, DETECTOR FOR MEASURING ELECTROMAGNETIC RADIATION REFLECTED ON A SOURCE SURFACE AND SYSTEM FOR THERMAL EVAPORATION WITH ELECTROMAGNETIC RADIATION

(71) Applicant: MAX-PLANCK-GESELLSCHAFT ZUR FÖRDERUNG DER WISSENSCHAFTEN E.V., München (DE)

(72) Inventor: Wolfgang Braun, Bietigheim-Bissingen (DE)

(21) Appl. No.: 18/013,866

(22) PCT Filed: Jun. 30, 2020
(86) PCT No.: PCT/EP2020/068404

§ 371 Date: Dec. 29, 2022

(51) Int. Cl. G01J 5/12; C23C 14/28; C23C 14/54; C23C 14/24; G01J 1/42; G01J 5/04

(52) U.S. Cl. CPC G01J 5/12; C23C 14/28; C23C 14/543; C23C 14/243; G01J 1/4257; G01J 5/042

(57) ABSTRACT

The present invention relates to a method for controlling an evaporation rate of source material (20) in a system (10) for thermal evaporation with electromagnetic radiation (120), wherein the system (10) comprises an electromagnetic radiation source (110) for providing an electromagnetic radiation (120), a vacuum chamber (12) containing a reaction atmosphere (16) and a main detector (40, 100) for measuring electromagnetic radiation (120), wherein a source material (20) and a target material (18) to be coated are arranged in the vacuum chamber (12) and the electromagnetic radiation source (110) is arranged such that its electromagnetic radiation (120) impinges at an angle, preferably at an angle of 45°, on a source surface (22) of the source material (20) for a thermal evaporation and/or sublimation of the source material (20) below the plasma threshold, and wherein the main detector (40, 100) for measuring electromagnetic radiation (120) is arranged such that electromagnetic radiation (120) reflected on the source surface (22) reaches the main detector (40, 100), further wherein the source material (20) is provided by a source element (24), wherein the source surface (22) is located accessible for the electromagnetic radiation (120) at the source element (24), whereby the source element (24) is arranged in a holding structure (28) and movable by the holding structure (28) perpendicular to the source surface (22). Further, the present invention relates to a detector (40) for measuring electromagnetic radiation (120), the detector (40) preferably suitable for a method according to the present invention, and additionally to a system (10) for thermal evaporation with electromagnetic radiation (120) suitable for the method according to the present invention.

The invention relates to a method for controlling an evaporation rate of source material in a system for thermal evaporation with electromagnetic radiation, wherein the system comprises an electromagnetic radiation source for providing an electromagnetic radiation, a vacuum chamber containing a reaction atmosphere and a main detector for measuring electromagnetic radiation, wherein a source material and a target material to be coated are arranged in the vacuum chamber and the electromagnetic radiation source is arranged such that its electromagnetic radiation impinges at an angle, preferably at an angle of 45°, on a source surface of the source material for a thermal evaporation and/or sublimation of the source material below the plasma threshold, and wherein the main detector for measuring electromagnetic radiation is arranged such that electromagnetic radiation reflected on the source surface reaches the main detector, further wherein the source material is provided by a source element, wherein the source surface is located accessible for the electromagnetic radiation at the source element, whereby the source element is arranged in a holding structure and movable by the holding structure.

Further the invention relates to a detector for measuring electromagnetic radiation reflected on a source surface, comprising a sensor element with an absorption body, the absorption body comprising an absorption surface for at least partly absorbing the electromagnetic radiation, wherein the sensor element further comprises a heat sensing element for measuring a temperature of the absorption body for detecting an absolute temperature and/or a temperature change caused in the absorption body by the absorbed electromagnetic radiation.

In addition, the invention relates to a system for thermal evaporation with electromagnetic radiation, comprising an electromagnetic radiation source for providing an electromagnetic radiation, a vacuum chamber containing a reaction atmosphere and a main detector for measuring electromagnetic radiation, wherein a source material and a target material to be coated are arranged in the vacuum chamber and the electromagnetic radiation source is arranged such that its electromagnetic radiation impinges at an angle, preferably at an angle of 45°, on the source surface of the source material for a thermal evaporation and/or sublimation of the source material below the plasma threshold, wherein the main detector for measuring electromagnetic radiation is arranged such that electromagnetic radiation reflected on the source surface reaches the main detector.

The usage of electromagnetic radiation, in particular laser light with a wavelength in the visible, infrared or ultra-violet range, for an evaporation of source material is commonly known. Such laser evaporation systems allow the deposition of thin films of materials at low pressures by heating the center of a block of source material with a continuous wave laser from the front side. For example, silicon melts at the temperatures required to achieve the desired flux of evaporated material, forming a melt pool inside a solid portion of the same source material. The solid Si therefore forms a crucible for the liquid Si, allowing for very high heating and cooling rates due to the absence of a thermal expansion mismatch between source material and crucible. At the same time, any contamination of the source material by a different crucible material is avoided. Alternatively, also crucibles consisting of a material different to the material to be evaporated are used.

However, as the source material is depleted by the impinging electromagnetic radiation, the source surface changes its shape as for instance a melt pool develops a concave form and/or a sublimation spot digs deeper and deeper into the source material. An evaporation rate and a flux distribution of the evaporated source material therefore is inherently unstable as the shape of the source surface directly influences the aforementioned evaporation rate and flux distribution of the evaporated material.

A known approach to overcome this problem is to move the spot of the electromagnetic radiation on the source material to obtain a more even distribution of the energy deposit and hence of the evaporated source material. Yet, since the support points for the source material are mostly located at its outer rim close to the evaporating surface, it is not practical to evaporate or sublimate from the entire surface of the source. In addition, the movement of the source itself also introduces variations as the evaporating surface still does not strictly have an at least temporally constant shape and/or orientation.

In view of the above, it is an object of the present invention to provide an improved method for controlling an evaporation rate of source material, an improved detector for measuring electromagnetic radiation reflected on a source surface and an improved system for thermal evaporation with electromagnetic radiation which do not have the aforementioned drawbacks of the state of the art. In particular it is an object of the present invention to provide a method, a detector and a system which allow a control of an evaporation rate of source material in a system for thermal evaporation with electromagnetic radiation in an especially easy and cost-efficient way, wherein preferably the evaporation rate can be adjusted both for higher and lower values, respectively, in particular in a closed loop control.

This object is satisfied by the respective independent patent claim. In particular, this object is satisfied by a method according to claim 1, by a detector according to claim 12 and by a system according to claim 29. The dependent claims describe preferred embodiments of the invention. Details and advantages described with respect to the method according to the first aspect of the invention also refer to a detector according to the second aspect of the invention and to a system according to the third aspect of the invention and vice versa, if of technical sense.

According to a first aspect of the invention, the object is satisfied by a method for controlling an evaporation rate of source material in a system for thermal evaporation with electromagnetic radiation, wherein the system comprises an electromagnetic radiation source for providing an electromagnetic radiation, a vacuum chamber containing a reaction atmosphere and a main detector for measuring electromagnetic radiation, wherein a source material and a target material to be coated are arranged in the vacuum chamber and the electromagnetic radiation source is arranged such that its electromagnetic radiation impinges at an angle, preferably at an angle of 45°, on a source surface of the source material for a thermal evaporation and/or sublimation of the source material below the plasma threshold, and wherein the main detector for measuring electromagnetic radiation is arranged such that electromagnetic radiation reflected on the source surface reaches the main detector, further wherein the source material is provided by a source element, wherein the source surface is located accessible for the electromagnetic radiation at the source element, whereby the source element is arranged in a holding structure and movable by the holding.

The method according to the present invention comprises the following steps:
a) Providing the electromagnetic radiation by the electromagnetic radiation source,
b) Measuring electromagnetic radiation reflected on the source surface by the main detector,
c) Analyzing the measured data obtained in step b), and
d) Adjusting the evaporation rate based on the results of the analysis of step c) by
   Moving the source element with respect to the electromagnetic radiation, and/or
   Adjusting the power of the electromagnetic radiation and/or
   Adjusting the size and/or shape of a cross section of the electromagnetic radiation.

A method according to the present invention can be used in and by a system for thermal evaporation of a source material with electromagnetic radiation. The evaporated source material can preferably be used to coat a target material, for instance in the form of a thin film. The source material and the target material are placed in a vacuum chamber of the system, wherein the vacuum chamber contains a reaction atmosphere suitable for the desired coating of the target material. For instance, the reaction atmosphere can be provided as a vacuum or contain required reaction gases like oxygen and/or nitrogen.

For the evaporation process, the electromagnetic radiation source provides the electromagnetic radiation, which is led into the vacuum chamber and impinges on the source surface of the source material. The energy deposit of the electromagnetic radiation evaporates or sublimates the source material. The energy deposit is chosen such that the plasma threshold of the source material is not reached. Hence, a purely thermal evaporation of the source material, especially without any forming of plasma, can be provided. By impinging at an angle, preferably an angle of 45°, a conflict of the path of the electromagnetic radiation in the vacuum chamber with other structures in the vacuum chamber such as source and/or target holding elements, can be avoided.

Only a fraction of the electromagnetic radiation impinging on the source surface is absorbed by the source material and used for the evaporation process. The remaining part of the electromagnetic radiation is reflected on the source surface. In other words, the absorbed part and the reflected part of the electromagnetic radiation are directly linked to each other. By detecting the reflected part, the amount of electromagnetic radiation absorbed by the source material can be deducted. For the detection of the reflected electromagnetic radiation, in the method according to the present invention a main detector is used, suitably positioned within the vacuum chamber in the path of the reflected electromagnetic radiation.

As described above, the measured reflected electromagnetic radiation allows deducting the energy deposit into the source material and hence the evaporation rate of source material. As the desired evaporation rate is known, it can be identified, whether the actual evaporation rate is too high or too low.

In particular, the system for the method according to the present invention comprises a holding structure for the source element, which is able to move the source element with respect to the electromagnetic radiation. Hence, based on the measured reflected electromagnetic radiation and the deducted actual evaporation rate, the relative position of the source surface and the impinging electromagnetic radiation can be altered to change the actual evaporation rate and for approximating the desired evaporation rate with the actual evaporation rate.

Hereinafter the individual steps of the method according to the present invention are described in detail.

In the first step a) of the method according to the present invention, the electromagnetic radiation is provided by the electromagnetic radiation source. The electromagnetic radiation source can be attached directly to the vacuum chamber. Alternatively, the electromagnetic radiation source can be positioned spaced apart from the vacuum chamber, even as far as in a different room or building. The electromagnetic radiation can be guided to the vacuum chamber by suitable guiding elements, for instance optical fibers. As a result, the electromagnetic radiation impinges on the source surface of the source material and thermally evaporates or sublimates source material below the plasma threshold.

Simultaneously, the part of the electromagnetic radiation not absorbed by the source material is reflected on the source surface. In the following step b) of the method according to the present invention, this reflected electromagnetic radiation is measured by the main detector of the system. For this purpose, the main detector is suitably positioned within the vacuum chamber.

The measurement data obtained in step b) of the method according to the present invention is analyzed in the subsequent step c). As the response function of the detector, the properties of the impinging electromagnetic radiation and the desired evaporation rate are known, the required absorbed electromagnetic radiation remaining and hence also the reflected part of the electromagnetic radiation is determined. By comparing the measurements of the main detector of step b) and the expectation with respect to the reflected electromagnetic radiation, it can be deduced whether the desired evaporation rate is met.

If the actual evaporation rate deduced in step c) differs from the desired evaporation rate, in the last step d) of the method according to the present invention, the evaporation rate can be adjusted to meet the specifications. This adjustment can be provided by different measures.

For instance, by moving the source element, the illumination of the source surface by the impinging electromagnetic radiation can be altered. Consequently, also the evaporation rate rises and diminishes, respectively.

Alternatively or additionally, also a power, in particular the power density, and/or the size and/or shape of the cross section of the electromagnetic radiation can be adjusted. The power of the electromagnetic radiation directly influences the evaporation rate, as a higher power results in a higher energy deposit. By altering a size and/or shape of the cross section of the electromagnetic radiation, the adaptation of the impinging electromagnetic radiation to the size and/or shape of the source surface can be altered, in particular improved. A better, preferably complete, illumination of the source surface by the electromagnetic radiation also leads to an increased evaporation rate.

In summary, the method according to the present invention described above allows an active adjustment of the evaporation rate during the operation of the respective evaporation system based on actual measurements. Hence, a control of the evaporation rate is possible. Consequently, the coating of target material can also be improved by the method according to the present invention.

Further, a method according to the present invention can comprise that in step d) the source element is moved perpendicular and/or parallel to the source surface. A movement of the source element perpendicular to the source surface shifts the source surface towards and away from the center of the impinging electromagnetic radiation, By moving the source element parallel to the source surface, the reflected part of the radiation can be maximized, corresponding to maximum absorption, which often coincides with a centering of the beam on the source surface.

In addition, the method according to the present invention can be characterized in that the source element is provided as self-supporting structure, in particular as a rod, comprising, in particular consisting of, source material with the source surface located at an upper end of the source element, in particular of the rod. In this embodiment, the source element is self-supporting, in other words, no additional crucible is needed to provide the source material in the vacuum chamber. Contamination of the source material due to reactions with the material of the crucible can therefore be avoided. In particular, the self-supporting source element carries the source surface on its upper end. The holding structure, for instance some suitably arranged wheels or pulleys, can be arranged spaced apart from the source surface. This can especially easily be provided in the embodiment of the source element as a rod. The source element, in particular the rod, can be moved up and down in step d) of the method according to the present invention to adjust the illumination of the source surface on its upper end by the electromagnetic radiation and hence acts similar to a of a candle, the radiation taking the place of the wick, and a proper relative adjustment of wick and candle diameters leading to a stationary consumption of the wax, without dripping or the formation of walls at the rim.

In a further improved embodiment of the method according to the present invention, the rod is provided with a circular or at least essentially circular rod cross section and the electromagnetic radiation is provided with an elliptical beam cross section, whereby the rod cross section and the beam cross section are chosen adapted to each other. As the electromagnetic radiation impinges on the source surface at an angle, preferably at an angle of 45°, the elliptical cross section is projected onto the source surface. The adaptation of the cross section of the electromagnetic radiation with respect to the circular cross section of the source surface can preferably be chosen such that the aforementioned projection of the electromagnetic radiation on the source surface is also circular. In other words a complete illumination of the source surface can be provided, and additionally also an outshining of the source surface by the electromagnetic radiation can be prohibited. In addition, the adaptation of the elliptical cross section of the electromagnetic radiation provides an especially even and conform illumination of the source surface.

According to an alternative embodiment of the method according to the present invention, the source element comprises a crucible containing the source material, whereby the crucible is transparent or at least partly transparent for the electromagnetic radiation, with the source surface located within the crucible. This embodiment is especially preferred for source materials which cannot be provided as self-supporting source elements. Especially, the crucible is chosen transparent for the electromagnetic radiation, for instance by using a crucible comprising or consisting of sapphire. Hence the evaporation of the source material is not hindered by the crucible, even if the source surface is located within the crucible, for instance after some evaporation of source material. Also in this embodiment, the crucible can be moved up and down to provide the movement of the source material perpendicular to the source surface. Hence the advantages of the method described above, in particular the adjustment of the evaporation rate based on measurements of electromagnetic radiation reflected on the source surface, can also be provided in this special embodiment comprising an additional and separate crucible.

Further, the method according to the present invention can comprise that as the electromagnetic radiation light, in particular laser light, with a wavelength between 100 nm and 1400 nm is used. Light, in particular laser light, is easy to provide and in particular can be easily guided from light sources spaced apart from the vacuum chamber to the vacuum chamber. In particular, light can also be provided with a wide range of energy densities and hence a provision of electromagnetic radiation for evaporation below the plasma threshold of the specific source material can easily be provided.

In particular, the method according to the present invention can be improved by that in step b) a main detector with two or more sensor elements is used, whereby the two or more sensor elements are adjacent to each other and thermally decoupled. During the evaporation, the source surface may change its spatial shape, especially the source surface can establish a convex or concave shape. This spatial shape of the source surface also influences the measurement results of the main detector, as focusing and defocusing effects occur and parts of the reflected electromagnetic radiation simply miss the main detector. By providing a main detector with two or more sensor elements, a more precise measurement of the reflected electromagnetic radiation can be obtained. In particular, changes in the spatial shape of the source surface can be detected, as these changes result in detectable differences in the reflected electromagnetic radiation measured by the two or more sensor elements. By providing these two or more sensor elements thermally decoupled, an independent measurement of each sensor element can be provided. The arrangement of the sensor elements adjacent to each other ensures that gaps between the sensor elements, in which the reflected electromagnetic radiation eludes the main detector, are minimized.

Further, the method according to the present invention can be characterized by that in step b) a first additional detector is used for measuring electromagnetic radiation reflected on a side surface of the source element different to the source surface, in particular perpendicular to the source surface, whereby the data measured by the first additional detector is used in steps c) and d). In a perfectly aligned position, the electromagnetic radiation impinges on the source surface with its entire cross section. Hence, the power of the incoming electromagnetic radiation is either absorbed by the source material or reflected in direction of the main detector. However, if the source surface is above this ideal position described above, a fraction of the incident electromagnetic radiation is reflected off the front face of the source element, for instance of the self-supporting rod or a suitable provided part of an otherwise transparent crucible. In this case, the intensity of the electromagnetic radiation reflected on the source surface, and subsequently measured by the main detector, is lowered by the amount of the incoming electromagnetic radiation reflected on the source element. However, by providing a first additional detector, this fraction of the incoming electromagnetic radiation reflected on the side surface of the source element can be measured and subsequently be considered by the determination of the necessary adjustments provided in step d) of the method according to the present invention. The adjustments of the evaporation rate can thereby be improved.

In addition, the method according to the present invention can further be improved by that the side surface of the source element is provided flat. A flat surface reflects an incoming electromagnetic radiation in an especially predictable way. In particular, a dispersion of the reflected electromagnetic radiation, as occurring by reflection on an arced surface, can be avoided. Hence, the analysis of the measurements of the first additional detector carried out in step c) of the method according to the present invention can be simplified.

According to a further improved embodiment of the method according to the present invention, the flat side surface is oriented perpendicular to a plane spanned by the directions of the electromagnetic radiation impinging and reflected on the source surface. In other words, the electromagnetic radiation is reflected on the side surface in the same plane as the electromagnetic radiation reflected on the source surface. A distortion of the cross section of the electromagnetic radiation reflected on the flat side surface, as it may occur by a grazing reflection, can be avoided and the respective cross section stays especially small and undistorted.

Alternatively or preferred additionally, the method according to the present invention can comprise that in step b) a second additional detector is used for measuring electromagnetic radiation missing the source surface of the source element, whereby the data measured by the second additional detector is used in steps c) and d). As already pointed out above, in a perfectly aligned position, the electromagnetic radiation impinges on the source surface with its entire cross section and the power of the incoming electromagnetic radiation is either absorbed by the source material or reflected in direction of the main detector. However, if the source surface is below this ideal position described above, a fraction of the incident electromagnetic radiation misses the source surface, in particular the whole source element. In this case, the intensity of the electromagnetic radiation reflected on the source surface, and subsequently measured by the main detector, is lowered by the amount of the incoming electromagnetic radiation missing the source element. However, by providing a second additional detector, this fraction of the incoming electromagnetic radiation missing the source element can be measured and subsequently be considered by the determination of the necessary adjustments provided in step d) of the method according to the present invention. The adjustments of the evaporation rate can thereby be improved.

As described above, the first additional detector can be used to identify a position of the source element above the ideal position, the second additional detector can be used to identify a position of the source element below the ideal position. Consequently, it is especially preferred to provide both, the first additional detector and the second additional detector, respectively. The measured intensity at the first additional detector increases with increasing upward deviation of the source element, the intensity at the second additional detector increases with increasing downward deviation of the source element. Combining both signals, a reliable and unambiguous position control of the source element can be implemented. By relating the relative intensities of the detectors, changes in the incoming electromagnetic radiation can be detected as a proportional change in the signals of pairs of detectors, or all three. This allows the variation and control of the overall electromagnetic radiation magnitude, without triggering a correction movement of the source element, and thereby an independent control and optimization of both quantities. Likewise, a focusing or defocusing of the electromagnetic radiation leads to an antiproportional intensity variation between the main detector and the additional detectors enabling do distinguish, and thereby to independently control, the focus of the electromagnetic radiation and the position of the source element.

Additionally, with non-constant incident laser intensity, as it is required for instance for the flux variation and control, the detector intensities not only depend on the position of the source element, but also on the incident laser intensity. With three measured values for two unknowns, namely the source position and the initial intensity of the electromagnetic radiation, however, the equation system is uniquely determined, and an unambiguous determination of both the incident laser intensity and the position of the source element can be made. For a less accurate operation, or in general for additional verification, however, the primary intensity of the electromagnetic radiation provided and measured by the electromagnetic radiation source as measured itself, may be used in addition, although it is affected by possible variable losses in the entrance window due to coating of the same.

Further, also an impinging electromagnetic radiation can be used, whose cross section outshines the source surface as default even in an ideal setup. In this case, the first and second additional detectors always detect some electromagnetic radiation. Also in this embodiment, the amount of detected electromagnetic radiation in all three implemented detectors can be used to adjust the position of the source element and hence to control the evaporation rate. When operating with a typical Gaussian shape of the beam, the parts outshining the source are much smaller in intensity than at the center of the beam, allowing this preferred mode of operation without significant power loss and associated reduction in efficiency.

According to a second aspect of the present invention, the object is satisfied by a detector for measuring electromagnetic radiation reflected on a source surface, comprising a sensor element with an absorption body, the absorption body comprising an absorption surface for at least partly absorbing the electromagnetic radiation, wherein the sensor element further comprises a heat sensing element for measuring a temperature of the absorption body for detecting an absolute temperature and/or a temperature change caused in the absorption body by the absorbed electromagnetic radiation, wherein the absorption body comprises a cooling system for an active cooling of the absorption body, whereby the cooling system comprises at least one cooling duct within the absorption body for a flow of coolant, preferably water, through the absorption body, and wherein the heat sensing element comprises flow sensors to measure the flow of the coolant through the cooling ducts in the absorption body and temperature sensors to measure an absolute temperature of the coolant and/or a temperature change of the coolant induced by flowing through the cooling ducts in the absorption body.

A detector according to the present invention can be used in a system for thermal evaporation with electromagnetic radiation. In particular, such a detector can be used to measure the electromagnetic radiation, for instance electromagnetic radiation reflected on a source surface of a source material.

The electromagnetic radiation to be measured impinges on the absorption body, in particular onto the absorption surface, and is at least partly absorbed by the absorption surface. In other words, at least a fraction of the energy of the electromagnetic radiation is deposited into the absorption body. Hence measuring and monitoring, respectively, of a temperature of the absorption body allows to determine the energy deposited into the absorption body and thereby to determine the amount of electromagnetic radiation impinging on the absorption surface.

The absorption surface faces the source surface at least partly. Therefore the absorption surface gets coated with the source material evaporated or sublimated of the source. After a sufficiently long deposition, the detector therefore has the same, which also implies a constant, absorptivity and reflectivity as the source.

The absorption surface can be for instance aligned perpendicular to an assumed impinging direction of the electromagnetic radiation to be measured. As only part of the impinging electromagnetic radiation will be absorbed, the remaining part will be reflected back into the same direction. In a system for thermal evaporation, in which the detector according to the present invention is used to measure electromagnetic radiation reflected on a source surface, the electromagnetic radiation reflected on such an absorption surface is directed back onto the source surface and can be used for thermal evaporation for a second time.

However, a subsequent second reflection on the source surface leads the electromagnetic radiation back to the electromagnetic radiation source and can cause disturbances. An embodiment of the absorption surface with two flat sections arranged adjacent to each other in an angle slightly less than 90°, for instance 89°, can solve this issue. The electromagnetic radiation can still be reflected back onto the source surface, but not exactly in the same direction and thereby missing the electromagnetic radiation source. In addition, as the electromagnetic radiation impinging on the two-fold absorption surface is reflected twice, also absorption of the impinging electromagnetic radiation by the absorption surface is doubled. The energy deposit into the absorption body and hence the precision of the measurement can thereby be enhanced.

To measure and/or monitor the amount of energy deposited into the absorption body by the impinging electromagnetic radiation, an absolute temperature and/or a change of the temperature of the absorption body can be measured and/or monitored. In the detector according to the present invention, this measurement is carried out by using the cooling system of the detector.

A cooling duct of the cooling system runs through the absorption body and allows a flow of coolant through the absorption body. The coolant can be a fluid, preferably water is used as coolant. By flowing through the absorption body, the coolant cools the absorption body. Preferably, the cooling system maintains the feed at a constant temperature. In other words, the coolant flowing through the cooling duct in the absorption body preferably absorbs any energy deposited into the absorption body by the impinging electromagnetic radiation. Thereby the temperature of the coolant changes according to the amount of absorbed energy.

For measuring this temperature and/or a change in temperature of the coolant, the sensing element of the detector according to the present invention comprises two different types of sensors, namely flow sensors and temperature sensors. In particular, the flow sensors measure the flow rate of coolant flowing through the cooling duct. The temperature sensors measure the temperature of the coolant. In particular, the temperature of the coolant is measured at least at an outlet of the cooling duct, preferably also at an inlet of the cooling duct. The outlet temperature allows to detect a temperature change over time, presupposed that the coolant is provided at the inlet with constant temperature. By additionally measuring the inlet temperature of the coolant, this measurement of relative temperature changes can be improved. Especially, by combining the temperature measurements with the aforementioned flow measurement, an absolute value of an energy deposit caused by absorbed electromagnetic radiation into the absorption body can be determined. Especially, based on the measurements of the detector according to the present invention for instance of electromagnetic radiation reflected on a source surface, an evaporation rate of source material can be deducted and subsequently be controlled.

Preferably, the detector according to the present invention comprises that one or more detectors are usable in a method according to the first aspect of the invention as main detector and/or as first additional detector and/or as second additional detector. Hence all features and advantages described in detail with respect to a method according to the first aspect of the present invention can also be provided by the detector according to the second aspect of the present invention used as main detector, first additional detector or second additional detector.

In addition, the detector according to the present invention can be characterized in that the absorption surface absorbs light, in particular laser light, with a wavelength between 100 nm and 1400 nm. As mentioned above with respect to the method according to the first aspect of the present invention, light, in particular laser light, is suitable for an evaporation and/or sublimation of a broad range of possible source materials. By providing an absorption surface capable of absorbing light, the detector according to the present invention can be adapted to this special electromagnetic radiation. The adaptation can for instance include a suitable material chosen for the absorption body, on which the absorption surface is arranged. Additionally or alternatively, also an adaptably chosen coating of the absorption surface for an enhancement of absorption of light can be used.

According to another embodiment of the detector according to the present invention, the heat sensing element comprises a temperature sensor, in particular a thermocouple element, arranged in a bore in the absorption body, wherein the bore ends within the absorption body, preferably in the vicinity of the absorption surface. The bore allows arranging the temperature sensor near to the absorption surface and hence to improve the accuracy of the temperature measurement. By the temperature sensor within the absorption body, the actual temperature of the absorption body and/or a change of this temperature can be directly measured. This additionally measured temperature value can be used to check the measurement of the coolant temperature and/or to enhance the overall accuracy of the temperature measurement. In addition, if the temperature measurement based on the coolant fails or is completely missing, a measurement of the temperature of the absorption body and hence of the energy deposited into the absorption body by the electromagnetic radiation is still possible.

Further, the detector according to the present invention can preferably comprise that the absorption body comprises, in particular consists of, metal, in particular copper or aluminum. Metal as material for the absorption body provides several advantages. First of all, metals, in particular copper and aluminum, comprise high heat conduction. The detector according to the present invention is designed as a bolometer, which absorbs the impinging electromagnetic radiation and comprises sensor elements to measure a temperature and/or a temperature change caused by this absorption. Materials with high heat conduction are especially suitable for such bolometers. Further, metals are materials compatible for a usage under ultrahigh vacuum conditions. A contamination of such an ultrahigh vacuum as reaction atmosphere by the detector according to the present invention and vice versa can therefore be avoided.

According to a further preferred embodiment of the detector according to the present invention, the absorption body encloses at one end a hollow absorption volume, whereby the inner sidewalls of the absorption volume form the absorption surface and wherein the absorption volume comprises an absorption orifice, whereby the absorption orifice can be aligned to an assumed and/or determined impinging direction of the electromagnetic radiation to be measured. As mentioned above, in most of the cases also the absorption surface absorbs only a fraction of the impinging electromagnetic radiation, at least of the electromagnetic radiation directly impinging on the detector. In this preferred embodiment of the detector according to the present invention, the absorption surface is provided as inner sidewalls of a hollow absorption volume. The electromagnetic radiation impinging on the detector enters the absorption volume through an absorption orifice. Within the absorption volume, the electromagnetic radiation impinges on the absorption surface and is partly absorbed and partly reflected. As this reflection occurs within the absorption volume, which is preferably large with respect to the absorption orifice, there is a high probability that the reflected electromagnetic radiation misses the absorption orifice and hits again an inner sidewall of the absorption volume, in other words another section of the absorption surface. In an ideal case, this procedure repeats itself until the impinging electromagnetic radiation is completely or at least essentially completely absorbed by the absorption body. In this case, the energy deposit into the absorption body represents the total energy of the impinging electromagnetic radiation. Especially any coating of the absorption surface with evaporated source material is thereby rendered without effect.

A further improved embodiment of the detector according to the present invention can comprise that the absorption surface is partly conically shaped within the absorption volume, with a cone of the conically shaped absorption surface facing the absorption orifice. The cone can be shaped both as a protrusion and as a recess, respectively, whereby in the protrusion embodiment a tip of the cone faces the absorption orifice, and in the recess embodiment a base of the cone faces the absorption orifice. In other words, the impinging electromagnetic radiation traversing the absorption orifice hits first the conically shaped part of the absorption surface. As the cone faces the absorption orifice, any electromagnetic radiation reflected on the sides of the cone are directed somewhere into the absorption volume and definitely miss the absorption orifice. Hence the above described ideal case of a complete absorption of the impinging electromagnetic radiation in the absorption volume can be reached more easily.

In addition, the detector according to the present invention can be improved by that the part of the absorption volume forming a rim of the absorption orifice is tilted inward with respect to the absorption volume. Similar to the aforementioned cone opposite to the absorption orifice, also an inwardly tilted rim around the absorption orifice helps ensuring a reflection of electromagnetic radiation back into the absorption volume. Hence also in this embodiment of the detector according to the present invention, the above described ideal case of a complete absorption of the impinging electromagnetic radiation in the absorption volume can thereby be reached more easily.

Preferably, the detector according to the present invention comprises both, a conically shaped section opposite to the absorption orifice and a tilted rim surrounding the absorption orifice.

Another embodiment of the detector according to the present invention can be characterized in that the detector comprises an aperture with an aperture opening, wherein the aperture is arranged upstream with respect to the sensor element along the assumed and/or determined impinging direction of the electromagnetic radiation to be measured. Such an aperture can help defining the solid angle which can be surveyed by the detector according to the present invention. To enhance the definition of the solid angle, also two or more apertures can be used, respectively aligned and stacked upstream along the assumed and/or determined impinging direction. Preferably, the aperture is sized and arranged such that, for instance, a source surface illuminated by the electromagnetic radiation source is visible from the point of view of the detector and hence electromagnetic radiation reflected on the source surface can reach the detector. In addition, electromagnetic radiation originating from other locations within the vacuum chamber is stopped by the aperture and therefore the overall accuracy of the measurement of the detector according to the present invention can be improved.

According to a further improved embodiment of the detector according to the present invention, a size of the aperture opening is adapted to the absorption body, in particular to the absorption orifice, such that electromagnetic radiation coming through the aperture opening is impinging on the absorption surface, in particular through the absorption orifice, of the absorption body. In this embodiment, the aforementioned restriction of the field of view of the detector is improved further. As the aperture opening and the absorption body, especially the absorption orifice, are constructed adapted to each other, it can be ensured that all of the electromagnetic radiation coming through the aperture orifice can be registered by the detector. A loss of information can thereby be avoided or at least be minimized.

To further restrict and optimize the field of view, multiple successive apertures may be used. This is particularly useful for intense sources located close together that need to be measured at a large distance from the source.

In addition, the detector according to the present invention can be improved by that the detector comprises a shielding element, wherein the shielding element extends along the assumed impinging direction of the electromagnetic radiation to be measured between the aperture and the absorption body. Together with the aperture, the shielding element forms a volume in front of the detector only accessible for electromagnetic radiation coming through the aperture orifice. Scattered electromagnetic radiation, which completely misses the aperture and nevertheless would impinge on the absorption body, is stopped by the shielding element. The field of view of the detector can thereby be defined with improved precision.

Further, in another improved embodiment of the detector according to the present invention, the shielding element extends further along the assumed impinging direction of the electromagnetic radiation along the absorption body. Electromagnetic radiation impinging on the absorption body away from the absorption surface can nevertheless deposit energy into the absorption body and thereby distort the results measured by the detector. A shielding element further extending along the absorption body covers the absorption body and intercepts all incoming electromagnetic radiation. A distortion of the measurement of the detector can therefore be avoided or at least be minimized.

In another preferred embodiment, the detector according to the present invention can be characterized in that the detector comprises two or more sensor elements, whereby the two or more sensor elements are adjacent to each other and thermally decoupled. As already mentioned above, during the evaporation, the source surface may change its spatial shape, especially the source surface can establish a convex or concave shape. This spatial shape of the source surface also influences the measurement results of the detector, as part of the reflected electromagnetic radiation simply misses the main detector and/or other parts are even focused on the direction of the detector. By providing a detector with two or more sensor elements, a more precise measurement of the distribution of the reflected electromagnetic radiation can be obtained. In particular, even changes in the spatial shape and/or form of the source surface can be detected, as these changes result in detectable differences in the distribution of the reflected electromagnetic radiation measured by the two or more sensor elements. By providing these two or more sensor elements thermally decoupled, an independent measurement of each sensor element can be provided. The arrangement of the sensor elements adjacent to each other ensures that gaps between the sensor elements, in which the reflected electromagnetic radiation eludes the detector, are minimized.

In addition, the detector according to the present invention can be improved by that the two or more sensor elements are arranged in a rotationally symmetric pattern or in rows or in a matrix in a plane perpendicular or at least essentially perpendicular to the assumed and/or determined impinging direction of the electromagnetic radiation to be measured. The different patterns allow an adaption of the detector to different measurement purposes. For instance, a rotationally symmetric pattern allows identifying focusing issues on the electromagnetic radiation provided by the electromagnetic radiation source, whereby an arrangement in rows is especially useful to spot misalignments between this electromagnetic radiation and the source surface. A matrix, especially when a plurality of sensor elements is used, allows an even more detailed measurement of the distribution of the electromagnetic radiation reflected on the source surface.

A further improved embodiment of the detector according to the present invention can comprise that in a plane perpendicular or at least essentially perpendicular to the assumed and/or determined impinging direction of the electromagnetic radiation to be measured, the two or more sensor elements comprise one of the following shapes:
rectangle
square
circle
circular ring
circular ring segment

This list is not complete and can be expanded by further suitable shapes. In particular with the above mentioned arrangement patterns of the two or more sensor elements, a shape of the respective sensor element adaptedly chosen to the applied present pattern allows a compact and continuous arrangement of the respective sensor elements, without avoidable gaps between the separate sensor elements.

Further, the detector according to the present invention can be characterized in that the detector comprises arrangement elements for arranging the absorption body at a vacuum feedthrough. This especially preferred embodiment of the detector according to the present invention allows arranging the detector directly in and/or at a vacuum feedthrough of the vacuum chamber. All connections, for instance the inlet and outlet port of the coolant channel and the electric connection of the sensor elements, are accessible from outside of the vacuum chamber. Within the vacuum chamber, essentially only the absorption body is located, if present also the aperture and/or the shielding element. These elements can be provided in embodiments capable for ultrahigh vacuum. A mutual impairment of parts of the detector and the reaction atmosphere within the vacuum chamber can therefore be avoided.

According to a further improved embodiment of the detector according to the present invention, the arrangement elements comprise positioning elements for altering a position of the absorption body with respect to the vacuum feedthrough. The possibility to alter the position of the absorption body within the vacuum chamber can be used for instance to exchange the source material and/or the target material. Interfering of such exchanging procedures by the detector, in particular by the absorption body, can thereby be avoided. In particular, after a completion to the procedure, the absorption body can be rearranged near to the source element to enhance the measurement capability of the detector according to the present invention by enlarging the covered solid angle.

According to a third aspect of the invention, the object is satisfied by a system for thermal evaporation with electromagnetic radiation, comprising an electromagnetic radiation source for providing an electromagnetic radiation, a vacuum chamber containing a reaction atmosphere and a main detector for measuring electromagnetic radiation, wherein a source material and a target material to be coated are arranged in the vacuum chamber and the electromagnetic radiation source is arranged such that its electromagnetic radiation impinges at an angle, preferably at an angle of 45°, on the source surface of the source material for a thermal evaporation and/or sublimation of the source material below the plasma threshold, wherein the main detector for measuring electromagnetic radiation is arranged such that electromagnetic radiation reflected on the source surface reaches the main detector, wherein the system according to the third aspect of the present invention is adapted to carry out a method according the first aspect of the present invention. Hence all features and advantages described in detail with respect to a method according to the first aspect of the present invention can also be provided by a system according to the third aspect of the present invention which is adapted to carry out the method according to the first aspect of the present invention.

Preferably, the system according to the present invention can be improved by that at least the main detector, preferably every detector for electromagnetic radiation, is constructed according to the second aspect of the invention. In this special embodiment, all features and advantages described in detail with respect to a detector according to the second aspect of the present invention can also be provided by a system according to the third aspect of the present invention which comprises at least one detector according to the second aspect of the present invention.

The present invention is further described hereinafter with reference to illustrated embodiments shown in the accompanying drawings. There is shown:

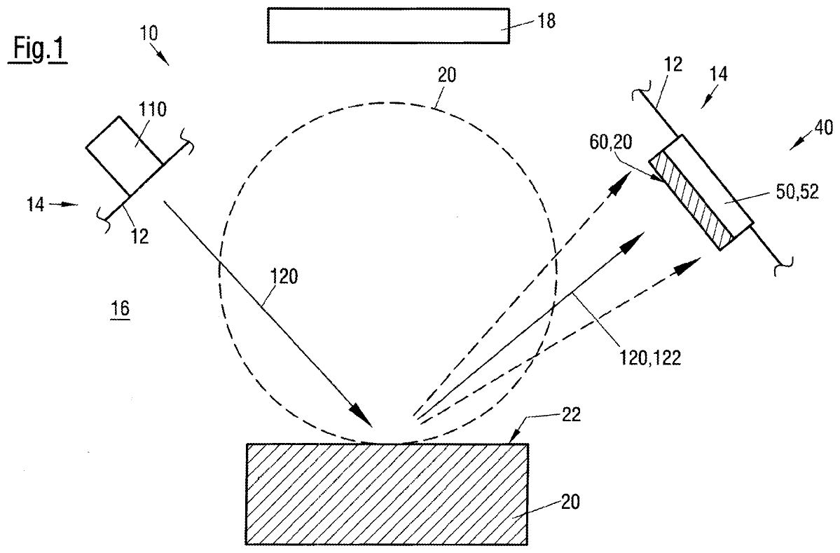

FIG. 1A system according to the present invention,

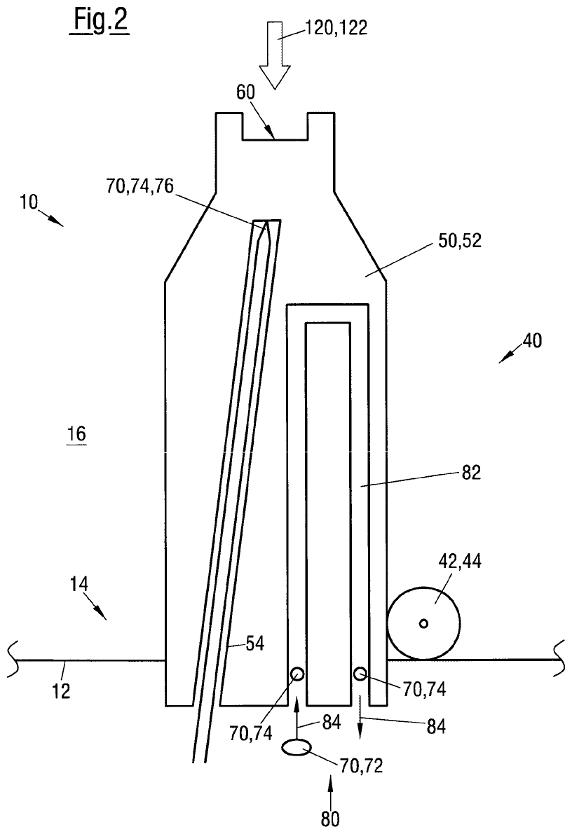

FIG. 2A first possible embodiment of the detector according to the present invention,

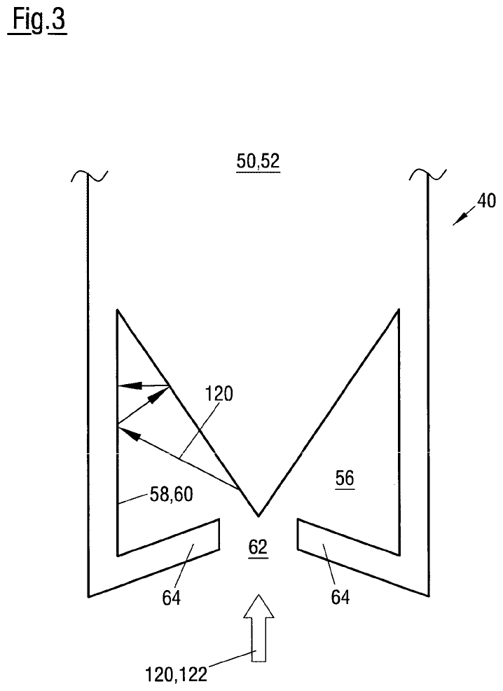

FIG. 3 An absorption body with an absorption volume,

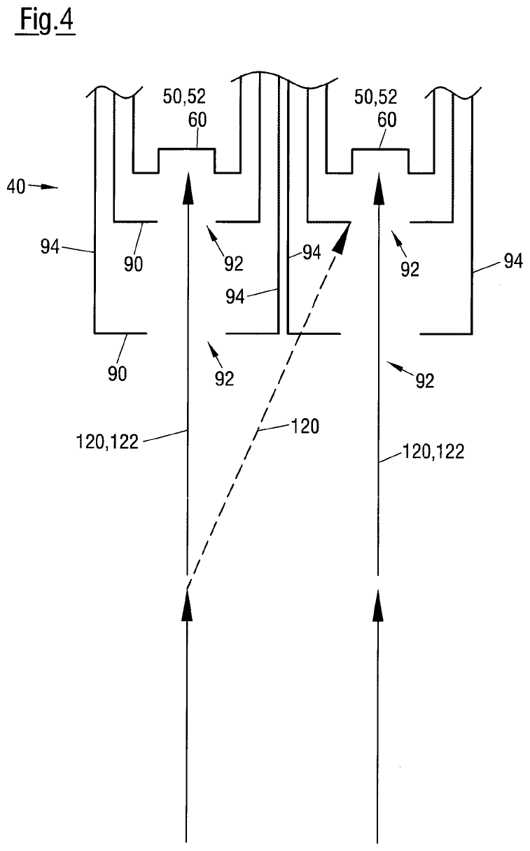

FIG. 4 An embodiment of the detector according to the present invention with two sensor elements,

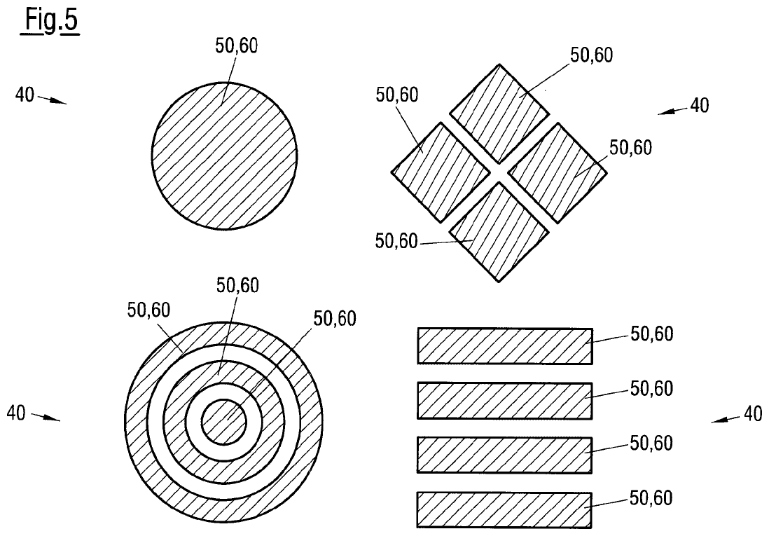

FIG. 5 Arrangement patterns of sensor elements,

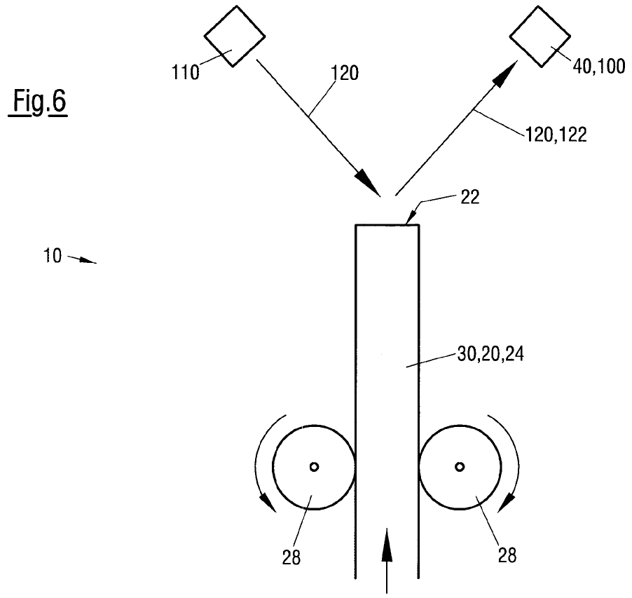

FIG. 6A movable source element,

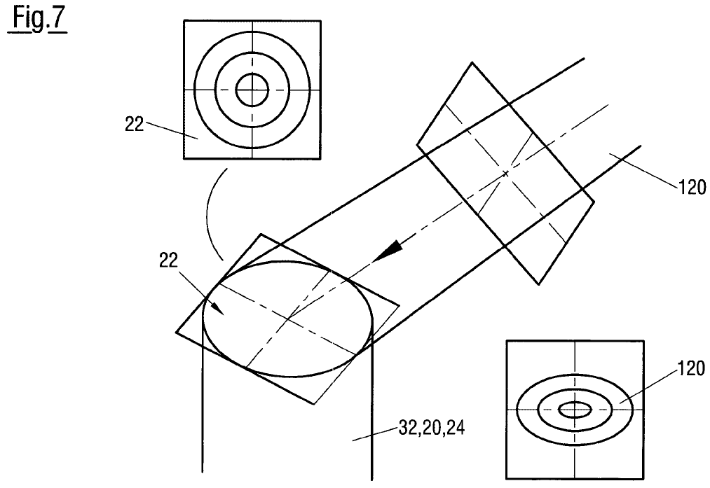

FIG. 7A cross section of the electromagnetic radiation adapted to the cross section of the source surface,

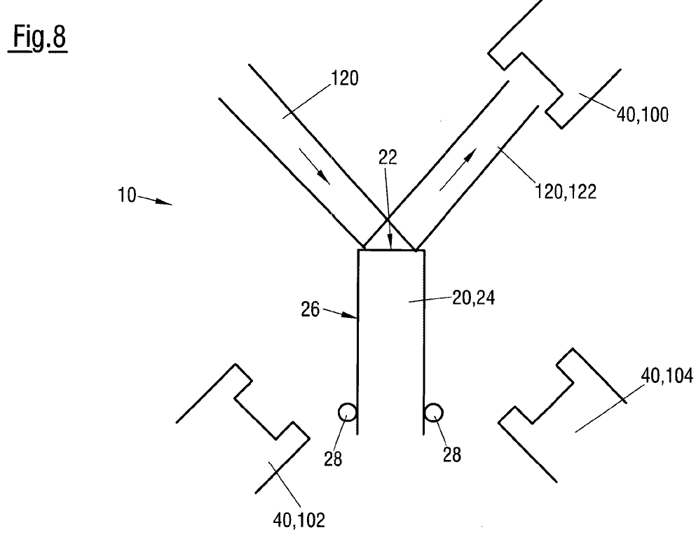

FIG. 8A system according to the present invention with a first condition of impinging electromagnetic radiation,

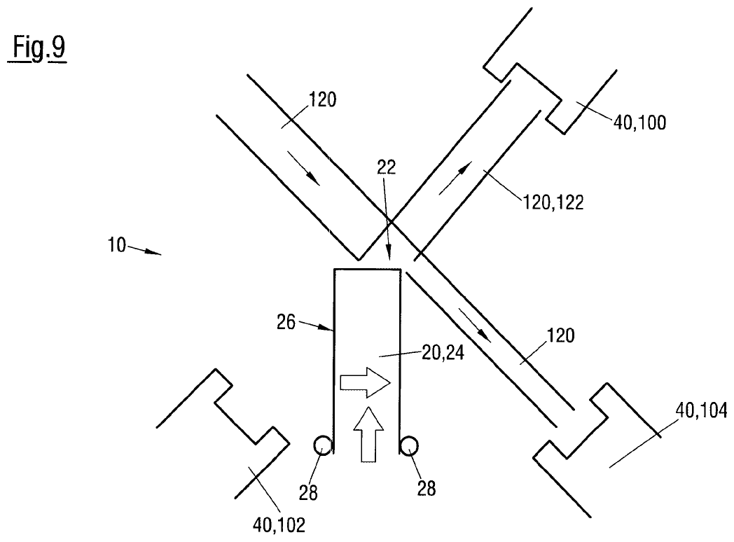

FIG. 9A system according to the present invention with a second condition of impinging electromagnetic radiation,

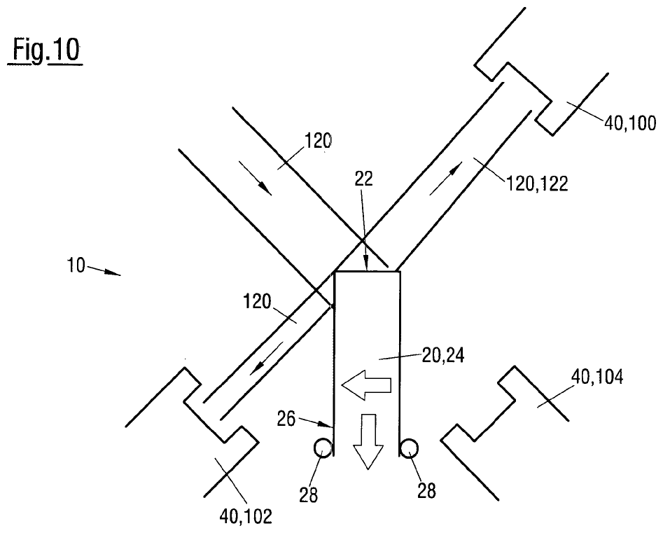

FIG. 10A system according to the present invention with a third condition of impinging electromagnetic radiation,

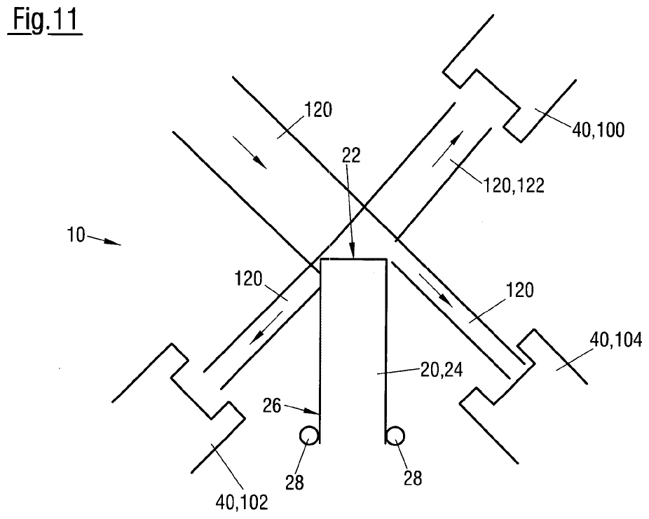

FIG. 11A system according to the present invention with a fourth condition of impinging electromagnetic radiation, and

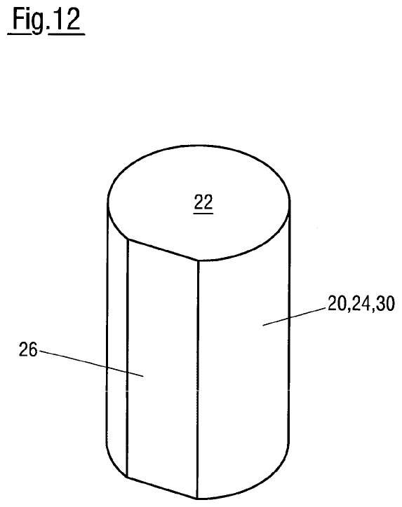

FIG. 12A source element provided as a rod.

In FIG. 1, the main components of a system 10 for thermal evaporation of source material 20 with electromagnetic radiation 120 according to the present invention are shown. The source material 20 is arranged within a vacuum chamber 12, whereby the vacuum chamber 12 confines a reaction atmosphere 16. The vacuum chamber 12 itself is only indicated next to a vacuum feedthrough 14. At one of the vacuum feedthroughs 14 an electromagnetic radiation source 110 is arranged, at the other a detector 40 according to the present invention.

During operation of the system 10, the electromagnetic radiation source 110 provides electromagnetic radiation 120 directed and impinging on the source surface 22 of the source material 20. The source material 20 absorbs a fraction of the electromagnetic radiation 120 and therefore some of the source material 20 evaporates or sublimates, indicated in FIG. 1 by the dashed circular line. Opposite to the source material 20, a target material 18 is arranged. The evaporated source material 20 reaches the target material 18 and forms a coating on the surface of the target material 18.

The remaining fraction of the electromagnetic radiation 120 is reflected on the source surface 20. As the emitting direction of the electromagnetic radiation source 110 and the position and general orientation of the source surface 22 are known, it is possible to arrange a detector 40 in the assumed and/or determined impinging direction 122 of the reflected electromagnetic radiation 120. As already described for the electromagnetic radiation source 110, also the detector, in particular its absorption body 52, can be arranged at a vacuum feedthrough 14 of the vacuum chamber 12.

The detector 40 according to the present invention acts as a bolometer. The electromagnetic radiation 120 impinges onto the absorption surface 60 of the absorption body 52 and gets absorbed at least partly. As depicted, the absorption surface 60 faces the source surface 22 and hence also gets coated by evaporated source material 20, indicated in FIG. 1. Hence, after a short build up time, the absorption surface 60 comprises the same or at least similar absorption and reflection properties as the source surface 22.

The aforementioned energy deposit into the absorption body 52 causes a change in temperature of the absorption body 52 or at least a rise of a demand for cooling. By measuring the temperature or its changing behavior, an evaporation rate and/or a flux distribution of the source material 20 evaporated or sublimated by the impinging electromagnetic radiation 120 can be determined.

FIG. 2 depicts a cross-section of a possible embodiment of detector 40 according to the present invention. The detector 40 can be used for instance as main detector 100, first additional detector 102 and/or second additional detector 104 in both the method and the system 10 according to the present invention, respectively (see FIGS. 8 to 11).

The detector 40 comprises a single sensor element 50 with an absorption body 52, preferably consisting of a metal with high thermal conduction like copper or aluminum. An arrangement element 40 allows arranging the absorption body 52 at a vacuum feedthrough 14 of the vacuum chamber 12 of the system 10 according to the present invention. In particular, the arrangement element 42 comprises positioning elements 44 to alter the actual position of the absorption body 52 within reaction atmosphere 16 of the vacuum chamber 12. A movement of other elements of the system 10 arranged in the vacuum chamber 12 as for instance the source material 20, see FIG. 1, can therefore be provided without any hindrance caused by the detector 40.

The detector 40 according to the present invention is based on the principle of a bolometer. Electromagnetic radiation 120 impinges onto an absorption surface 60 of the absorption body 52 and gets absorbed at least partially. This energy deposit can be measured by measuring the absolute temperature or a change of the temperature of the absorption body 52.

For this, in the depicted detector 40 according to the present invention two different measurement methods and respective sensing elements 70 are implemented. The respective methods can be used separately to measure the temperature or its change. However, higher accuracy can be provided by combining the two methods described in the following.

For the first method, the absorption body 52 comprises a cooling system 80 for an active cooling. Coolant 84 flows through a cooling duct 82 through the absorption body 52 and thereby assimilates the energy deposited into the absorption body 80 by the impinging electromagnetic radiation 120. Flow sensors 72 measure the flow rate of the coolant 84, temperature sensors 74 measure the temperature of the coolant 84, as depicted in FIG. 2 both at the inlet port and at the outlet port of the cooling duct 82, respectively. In summary, these measurements combined allow to precisely determine the amount of energy deposited into the absorption body 52.

For the second method, a temperature sensor 74, preferably a thermocouple element 74, is arranged in a bore 54 of the absorption body 52, in particular in the vicinity of the absorption surface 60. As mentioned above, the energy deposited by the electromagnetic radiation 120 impinging on the absorption surface 60 causes a rise in temperature of the absorption body 52. The thermocouple 76 located within the absorption body 52 near to the absorption surface 60 can measure this as absolute temperature or as a change in temperature. Hence, also this measurement method allows to precisely determine the amount of energy deposited into the absorption body 52.

FIG. 3 shows a cross-section of a rotationally symmetrical preferred embodiment of the detector 40 according to the present invention, in particular of its absorption surface 60. According to this embodiment, the absorption body 52 of the depicted sensor element 50 comprises at its end, which faces the impinging direction 122 of the electromagnetic radiation 120 to be measured, a hollow absorption volume 56. This absorption volume 56 comprises a single opening, namely an absorption orifice 62, which allows the impinging electromagnetic radiation 120 to enter the absorption volume 56. Inner sidewalls 58 of the absorption volume 56 form the absorption surface 60. In other words, the electromagnetic radiation 120 enters the absorption volume 120 and is reflected many times within the absorption volume 56, indicated in FIG. 3 by arrows, whereby at each reflection a fraction of the energy of the impinging electromagnetic radiation 120 is absorbed. Ideally, the electromagnetic radiation 120 is trapped in the absorption volume 56 and consequently completely absorbed by the absorption surface 60. To enhance a probability for this ideal case, the part of the sidewall which forms a rim 64 surrounding the absorption orifice 62 is tilted inward with respect to the absorption volume 56. This inwardly tilted surface provides the additional advantage that a reflection of electromagnetic radiation impinging on these surfaces back into the impinging direction can be avoided. In addition, the part of the absorption surface 60 arranged opposite of the absorption orifice 62 is conically shaped with the cone tip pointing towards the absorption orifice 62.

In FIG. 4 a detector 40 with two sensor elements 50 is shown. The sensor elements 50 are arranged adjacent to each other and thermally decoupled. Each sensor element 50 comprises its own absorption body 52 and absorption surface 60. The remaining parts of the sensor elements 50 are not shown. In summary, providing two or more sensor elements 50 can provide a more detailed information about the absorbed electromagnetic radiation 120, for instance for a determination of an evaporation rate and/or of a distribution of a flux of the evaporated source material 20 (not shown).

In addition, upstream of the each of the respective sensor elements 50, two stacked and aligned apertures 90 are arranged. The aperture openings 92 confine the solid angle of acceptance of the respective sensor element 50. Cross talk between the sensor elements 50, indicated by the dashed arrow, can be avoided. Further, between the apertures 90 and the absorption body 52, and even further along the respective aperture body 52, shielding elements 94 are arranged. These shielding elements 94 on one hand further diminish the aforementioned crosstalk. On the other hand, also electromagnetic radiation 120 impinging on a side surface of the absorption body 52 is stopped and cannot distort the measurement results.

As mentioned with respect to FIG. 4, the detector 40 according to the present invention can comprise two or more sensor elements 50. A few examples for shapes and arrangement patterns of sensor elements 50 and their absorption surfaces 60 are shown in FIG. 5. Obviously, other arrangements, in one limit a high-resolution pixel array similar to an electronic camera, are possible. In summary, out of the different arrangement patterns the most suitable can be chosen with respect to the purpose of the measurement of the detector 40, for instance a determination of an evaporation rate and/or of a distribution of a flux of the evaporated source material 20.

The standard geometry with a simple circular active area is shown in the top left panel of FIG. 5.

A movement of the impinging direction 122 of the electromagnetic radiation 120 can be detected with four quadrants as shown in the top right panel. Here, the sensor elements 50 are shaped as squares and are arranged such that primarily movements in the horizontal and vertical directions along their diagonals can be detected, while keeping the number of sensor elements 50 small.

The third arrangement with sensor elements 50 forming a rotationally symmetric pattern of circular rings is shown in the lower left panel of FIG. 5. This pattern is most sensitive to focusing or defocusing of the electromagnetic radiation 120 provided by the electromagnetic radiation source 110.

Both position and defocusing, although in this case only in the vertical direction, may be detected by a stripe arrangement of rectangular shaped sensor elements 50, such as shown in the lower right panel of FIG. 5. This can be favorable, as the electromagnetic radiation 120, being reflected in the impinging direction 122 around 45° on the source surface 22, is more strongly affected in the plane containing the incident and reflected beam, than perpendicular to it.

FIG. 6 depicts the basic elements of a system 10 according to the present invention, namely an electromagnetic radiation source 110, a source material 20 and a detector 40, in particular a main detector 100. As electromagnetic radiation 120 light, in particular laser light, with a wavelength between 100 nm and 1400 nm is used. In the following, the method according to the present invention will be described.

In the first step a) of the method according to the present invention, the electromagnetic radiation 120 is provided by the electromagnetic radiation source 110. The electromagnetic radiation 120 impinges on the source surface 22 of the source material 20, preferably at an angle of 45°, and thermally evaporates or sublimates source material 20 below the plasma threshold.

In the following step b) of the method according to the present invention, electromagnetic radiation 120 reflected on the source surface 22 is measured by the main detector 100 of the system 10. For this purpose, the main detector is suitably positioned within the vacuum chamber 12 (not shown).

The measurement data obtained in step b) of the method according to the present invention is analyzed in the subsequent step c). As the response function of the detector 40, the properties of the impinging electromagnetic radiation 120 and the desired evaporation rate, and hence the required absorbed electromagnetic radiation 120, are known, the remaining reflected part of the electromagnetic radiation 120 is also determined. By comparing the measurements of the main detector 100 of step b) and the expectation with respect to the reflected electromagnetic radiation 120, it can be deduced whether the desired evaporation rate is met.

If the actual evaporation rate deduced in step c) differs from the desired evaporation rate, in the last step d) of the method according to the present invention, the evaporation rate can be adjusted to meet the specifications. This adjustment can be provided by different measures.

As shown in FIG. 6, by moving the source element 20 perpendicular and/or parallel to the source surface 22, the illumination of the source surface 22 by the impinging electromagnetic radiation 120 can be altered, in particular shifted, enlarged and scaled down, respectively. Consequently, also the evaporation rate rises and diminishes, respectively. For this purpose, the source material 20 preferably is provided as self-supporting source element 24, for instance as a rod 30. A holding structure 28 can be used for providing the aforementioned movement of the source surface 22.

Alternatively or additionally and as shown in FIG. 7, also the size and/or shape of the cross section of the electromagnetic radiation 120 provided by the electromagnetic radiation source 110 can be adjusted. By altering a size and/or shape of the cross section of the electromagnetic radiation 120, the adaptation of the impinging electromagnetic radiation 120 to the size and/or shape of the source surface 22 can be altered, in particular improved. A better, preferably complete, illumination of the source surface 22 by the electromagnetic radiation 120 also leads to an increased evaporation rate. As depicted, the electromagnetic radiation 120 can for instance be provided with an elliptical cross section to match a circular cross section of the source surface 22 provided as melted pool of source material 20 confined in a crucible 32, whereby the crucible 32 is at least partly transparent for the electromagnetic radiation 120.

Further, also a power, in particular the power density, of the electromagnetic radiation 120 can be adjusted. The power of the electromagnetic radiation 120 directly influences the evaporation rate, as a higher power results in a higher energy deposit.

In summary, the method according to the present invention described above allows an active adjustment of the evaporation rate during the operation of the respective evaporation system 10 based on actual measurements. Hence, a control of the evaporation rate is possible. Consequently, the coating of target material 18 with source material 20 can also be improved.

The following FIGS. 8 to 11 show an embodiment of the system 10 according to the present invention, which comprises three detectors 40, the main detector 100, the first additional detector 102 and the second additional detector 104. As described above, the main detector 100 is arranged such that it can measure electromagnetic radiation 120 reflected on the source surface 22 in the impinging direction 122. The first additional detector 104 is arranged such that it can detect electromagnetic radiation 120 reflected on a side surface 26 of the source element 24, and finally the second additional detector 104 detects electromagnetic radiation 120 which misses the source element 24, in particular the source surface 22. In the following, different situations occurring during the operation of the depicted system 10 are described.

In FIG. 8, an ideal case of the operation of the system 10 is shown. The electromagnetic radiation 120 illuminates the source surface 22 and is partly reflected in the impinging direction 122 to the main detector 100. No electromagnetic radiation 120 reaches the remaining first and second additional detectors 102, 104. No actions are required for the holding structures 28.

FIG. 9 shows a different condition, as a fraction of the incoming electromagnetic radiation 120 misses the source element 24 and reaches the second additional detector 104. Based on the measurement signal of the second additional detector 104, in combination with the decreased sensor output of the main detector 100, it can be deduced that the source surface 22 is too low or too far left with respect to the incoming electromagnetic radiation 120. Hence, this triggers an activation of the holding structure 28 and the source element 24 is moved upwards or to the right as indicated by the depicted arrows.

In FIG. 10, the opposite condition is depicted, as a fraction of the incoming electromagnetic radiation 120 is reflected off the side surface 26 of the source element 24 and reaches the first additional detector 102. Analogous, based on the measurement signal of the first additional detector 102, in combination with the decreased sensor output of the main detector 100, it can be deduced that the source surface 22 is too high or too far to the right with respect to the incoming electromagnetic radiation 120. Hence, this triggers an activation of the holding structure 28 and the source element 24 is moved downwards or to the left as indicated by the depicted arrows.

FIG. 11 depicts another possible static condition during the operation of the system 10 according to the present invention. In this setting, the incoming electromagnetic radiation 120 outshines the source surface 22. In other words, the cross section of the incoming electromagnetic radiation 120 is larger than the cross section of the source surface 22. In this case, electromagnetic radiation 120 reaches all three detectors 40, the main detector 100 and both additional detectors 102, 104. As long as both additional detectors 102, 104 detect a predetermined or at least some electromagnetic radiation 120, a complete illumination of the source surface 22 can be assumed. If one of the additional detectors 102, 104 ceases to detect electromagnetic radiation 120, the position of the source element 24 can be accordingly be altered by triggering the holding structure 28 as described above.

By relating the relative intensities of the detectors, changes in the incoming electromagnetic radiation can be detected as a proportional change in the signals of pairs of detectors, or all three. This allows the variation and control of the overall electromagnetic radiation magnitude, without triggering a correction movement of the source element 24, and thereby an independent control and optimization of both quantities.

Likewise, a focusing or defocusing of the electromagnetic radiation leads to an antiproportional intensity variation between the main detector 100 and the additional detectors 102, 104, enabling do distinguish, and thereby to independently control, the focus of the electromagnetic radiation 120 and the position of the source element 24.

As the first additional detector 102 detects electromagnetic radiation 120 reflected on a side surface 26 of the source element 24, this side surface 26 is preferably provided flat. This is depicted in FIG. 11. The shown source element 24 is provided as self-supporting rod 30 consisting of source material 20. Preferably, the flat side surface 26 is perpendicularly oriented both to the source surface 22 and the incoming electromagnetic radiation 120 provided by the electromagnetic radiation source 110 (not shown).

### LIST OF REFERENCES

10 System

12 Vacuum chamber

14 Vacuum feedthrough

16 Reaction atmosphere

18 Target Material

20 Source material

22 Source surface

24 Source element

26 Side surface

28 Holding structure

30 Rod

32 Crucible

40 Detector

42 Arrangement element

44 Positioning element

50 Sensor element

52 Absorption body

54 Bore

56 Absorption volume

58 Sidewall

60 Absorption surface

62 Absorption orifice

64 Rim

70 Heat sensing element

72 Flow sensor

74 Temperature sensor

76 Thermocouple element

80 Cooling system

82 Cooling duct

84 Coolant

90 Aperture

92 Aperture opening

94 Shielding element

100 Main detector

102 First additional detector

104 Second additional detector

110 Electromagnetic radiation source

120 Electromagnetic radiation

122 Impinging direction

1.-30. (canceled)

31. Method for controlling an evaporation rate of source material in a system for thermal evaporation with electromagnetic radiation, wherein the system comprises an electromagnetic radiation source for providing an electromagnetic radiation, a vacuum chamber containing a reaction atmosphere and a main detector for measuring electromagnetic radiation, wherein a source material and a target material to be coated are arranged in the vacuum chamber and the electromagnetic radiation source is arranged such that its electromagnetic radiation impinges at an angle on a source surface of the source material for a thermal evaporation and/or sublimation of the source material below the plasma threshold, and wherein the main detector for measuring electromagnetic radiation is arranged such that electromagnetic radiation reflected on the source surface reaches the main detector, further wherein the source material is provided by a source element, wherein the source surface is located accessible for the electromagnetic radiation at the source element, whereby the source element is arranged in a holding structure and movable by the holding structure perpendicular to the source surface, the method comprising the following steps:
a) Providing the electromagnetic radiation by the electromagnetic radiation source,
b) Measuring electromagnetic radiation reflected on the source surface by the main detector,
c) Analyzing the measured data obtained in step b), and
d) Adjusting the evaporation rate based on the results of the analysis of step c) by
Moving the source element with respect to the electromagnetic radiation and/or
Adjusting the power of the electromagnetic radiation and/or
Adjusting the size and/or shape of a cross section of the electromagnetic radiation.

32. Method according to claim 31, wherein in step d) the source element is moved perpendicular and/or parallel to the source surface.

33. Method according to claim 31, wherein the source element is provided as self-supporting structure, comprising source material with the source surface located at an upper end of the source element.

34. Method according to claim 31, wherein the source element comprises a crucible containing the source material, whereby the crucible is transparent or at least partly transparent for the electromagnetic radiation, with the source surface located within the crucible.

35. Method according to claim 31, wherein as the electromagnetic radiation light, with a wavelength between 100 nm and 1400 nm is used.

36. Method according to claim 31, wherein in step b) a main detector with two or more sensor elements is used, whereby the two or more sensor elements are adjacent to each other and thermally decoupled.

37. Method according to claim 31, wherein in step b) a first additional detector is used for measuring electromagnetic radiation reflected on a side surface of the source element different to the source surface, whereby the data measured by the first additional detector is used in steps c) and d).

38. Method according to claim 31, wherein in step b) a second additional detector is used for measuring electromagnetic radiation missing the source surface of the source element, whereby the data measured by the second additional detector is used in steps c) and d).

39. Detector for measuring electromagnetic radiation reflected on a source surface, comprising a sensor element with an absorption body, the absorption body comprising an absorption surface for at least partly absorbing the electromagnetic radiation, wherein the sensor element further comprises a heat sensing element for measuring a temperature of the absorption body for detecting an absolute temperature and/or a temperature change caused in the absorption body by the absorbed electromagnetic radiation,
wherein the absorption body comprises a cooling system for an active cooling of the absorption body, whereby the cooling system comprises at least one cooling duct within the absorption body for a flow of coolant through the absorption body, and
wherein the heat sensing element comprises flow sensors to measure the flow of the coolant through the cooling ducts in the absorption body and temperature sensors to measure an absolute temperature of the coolant and/or a temperature change of the coolant induced by flowing through the cooling ducts in the absorption body.

40. Detector according to claim 39, wherein one or more detectors are as main detector and/or as first additional detector and/or as second additional detector in a method for controlling an evaporation rate of source material in a system for thermal evaporation with electromagnetic radiation, wherein the system comprises an electromagnetic radiation source for providing an electromagnetic radiation, a vacuum chamber containing a reaction atmosphere and a main detector for measuring electromagnetic radiation, wherein a source material and a target material to be coated are arranged in the vacuum chamber and the electromagnetic radiation source is arranged such that its electromagnetic radiation impinges at an angle on a source surface of the source material for a thermal evaporation and/or sublimation of the source material below the plasma threshold, and wherein the main detector for measuring electromagnetic radiation is arranged such that electromagnetic radiation reflected on the source surface reaches the main detector, further wherein the source material is provided by a source element, wherein the source surface is located accessible for the electromagnetic radiation at the source element, whereby the source element is arranged in a holding structure and movable by the holding structure perpendicular to the source surface, the method comprising the following steps:
e) Providing the electromagnetic radiation by the electromagnetic radiation source,
f) Measuring electromagnetic radiation reflected on the source surface by the main detector,
g) Analyzing the measured data obtained in step b), and
h) Adjusting the evaporation rate based on the results of the analysis of step c) by
Moving the source element with respect to the electromagnetic radiation and/or
Adjusting the power of the electromagnetic radiation and/or
Adjusting the size and/or shape of a cross section of the electromagnetic radiation.

41. Detector according to claim 39, wherein the absorption surface absorbs light, with a wavelength between 100 nm and 1400 nm.

42. Detector according to claim 39, wherein the heat sensing element comprises a temperature sensor arranged in a bore in the absorption body, wherein the bore ends within the absorption body.

43. Detector according to claim 39, wherein the absorption body comprises metal.

44. Detector according to claim 39, wherein the absorption body encloses at one end a hollow absorption volume, whereby the inner sidewalls of the absorption volume form the absorption surface and wherein the absorption volume comprises an absorption orifice, whereby the absorption orifice can be aligned to an assumed and/or determined impinging direction of the electromagnetic radiation to be measured.

45. Detector according to claim 39, wherein the detector comprises an aperture with an aperture opening, wherein the aperture is arranged upstream with respect to the sensor element along the assumed and/or determined impinging direction of the electromagnetic radiation to be measured.

46. Detector according to claim 45, wherein a size of the aperture opening is adapted to the absorption body, such that electromagnetic radiation coming through the aperture opening is impinging on the absorption surface of the absorption body.

47. Detector according to claim 45, wherein the detector comprises a shielding element, wherein the shielding element extends along the assumed impinging direction of the electromagnetic radiation to be measured between the aperture and the absorption body.

48. Detector according to claim 39, wherein the detector comprises two or more sensor elements, whereby the two or more sensor elements are adjacent to each other and thermally decoupled.

49. Detector according to claim 39, wherein the detector comprises arrangement elements for arranging the absorption body at a vacuum feedthrough.

50. System for thermal evaporation with electromagnetic radiation, comprising an electromagnetic radiation source for providing an electromagnetic radiation, a vacuum chamber containing a reaction atmosphere and a main detector for measuring electromagnetic radiation, wherein a source material and a target material to be coated are arranged in the vacuum chamber and the electromagnetic radiation source is arranged such that its electromagnetic radiation impinges at an angle on the source surface of the source material for a thermal evaporation and/or sublimation of the source material below the plasma threshold, wherein the main detector for measuring electromagnetic radiation is arranged such that electromagnetic radiation reflected on the source surface reaches the main detector, wherein the system is adapted to carry out a method according to claim 31.
